(19) United States
(12) Patent Application Publication
(10) Pub. No.: US 2014/0106576 A1
(43) Pub. Date: Apr. 17, 2014

(54) INORGANIC POLYSILAZANE, SILICA FILM-FORMING COATING LIQUID CONTAINING SAME, AND METHOD FOR FORMING SILICA FILM

(71) Applicants: Hiroshi Morita, Tokyo (JP); Atsushi Kobayashi, Tokyo (JP); Hiroo Yokota, Tokyo (JP); Yasuhisa Furihata, Tokyo (JP)

(72) Inventors: Hiroshi Morita, Tokyo (JP); Atsushi Kobayashi, Tokyo (JP); Hiroo Yokota, Tokyo (JP); Yasuhisa Furihata, Tokyo (JP)

(73) Assignee: ADEKA CORPORATION, Tokyo (JP)

(21) Appl. No.: 14/113,305

(22) PCT Filed: Apr. 9, 2012
(86) PCT No.: PCT/JP2012/059655

§ 371 Date: Oct. 22, 2013

(30) Foreign Application Priority Data
Jun. 13, 2011 (JP) 2011-131146

(51) Int. Cl. H01L 21/02; C09D 1/00; C01B 21/087

(52) U.S. Cl. CPC H01L 21/02164; C01B 21/087; C09D 1/00; H01L 21/02282
USPC 438/787; 423/324; 106/287.11

(57) ABSTRACT

Disclosed is an inorganic polysilazane that undergoes less shrinkage during a calcination step in an oxidizing agent such as water vapor and is less prone to allow a silica film to suffer from the formation of cracks or peel off from a semiconductor substrate, and a silica film-forming coating liquid containing the inorganic polysilazane, and also provides an inorganic polysilazane and a silica film-forming coating liquid containing the same. The value of A/(B+C) is 0.9-1.5 and the value of (A+B)/C is 4.2-50. A=peak area within the range of from 4.75 ppm to less than 5.4 ppm. B=peak area within the range of from 4.5 ppm to less than 4.75 ppm. Peak area within the range of from 4.2 ppm to less than 4.5 ppm is represented by C in a ¹H-NMR spectrum; and the polystyrene-equivalent mass average molecular weight is 2000 to 20000.

### TECHNICAL FIELD

The present invention relates to a specifically configured inorganic polysilazane, a silica film-forming coating liquid including the inorganic polysilazane and an organic solvent as essential ingredient, and a method for forming a silica film.

### BACKGROUND ART

Silica films containing silicon oxide as the main ingredient thereof are widely used as hard coat materials and insulating films for semiconductor devices because they are superior in insulating properties, heat resistance, abrasion resistance, and corrosion resistance. Along with the miniaturization of semiconductor devices, insulating materials capable of filling up narrow gaps have been desired. The insulating films to be used for semiconductor devices are formed by, for example, a CVD (Chemical Vapor Deposition) process or a coating process. Since the coating process is advantageous in terms of cost and productivity, a variety of materials have been studied for improving the quality.

Polysilazanes are polymeric compounds containing —SiH₂—NH— as a fundamental unit, and silica films of good quality containing silica oxide as a main ingredient can be formed therefrom in narrow gaps by the coating process, which is a relatively inexpensive process.

There is known as a method for forming a silica film using a polysilazane a method including 1) an application step of applying a solution of the polysilazane in xylene, dibutyl ether, or the like to a semiconductor substrate or the like by spin coating or the like, 2) a drying step of evaporating the solvent by heating to about 150° C. the semiconductor substrate or the like on which the polysilazane has been applied, and 3) a calcination step of calcining the semiconductor substrate or the like at about 230 to about 900° C. in the presence of an oxidizing agent such as water vapor (see, for example, Patent Literatures 1 and 2). The polysilazane is converted into silica during the calcination step using water vapor.

The reaction in which the polysilazane is converted into silica by water vapor, an oxidizing agent, during the calcination step is known to be expressed by the following reaction formula (1) and reaction formula (2) (see, for example, Non-Patent Literature 1).

[Chemical Formula 1]

—(SiH₂—NH)—+2H₂O→—(SiO₂)—+NH₃+2H₂ (1)

—(SiH₂—NH)—+2O₂→—(SiO₂)—+NH₃ (2)

During the formation of a silica film using a polysilazane, shrinkage occurs as the polysilazane coating film changes to the silica film. In order to increase the reactivity of the polysilazane to silica and improve insulation by reducing silanol groups (Si—OH) on the surface of silica, the calcination step in water vapor is desirably conducted at a higher temperature, but the calcination at a higher temperature will promote such shrinkage. In the event that the shrinkage during the calcination step in water vapor is high, cracking in a silica film or exfoliation of a silica film from a semiconductor substrate may occur, and especially in the event that in inorganic polysilazane is used for an element isolation application in which narrow gaps between elements of a semiconductor device are filled up and calcination is conducted at a high temperature, there was a problem that cracking or exfoliation would readily occur. Because of a future desire for semiconductor devices with further narrowed distance between semiconductor elements, inorganic polysilazanes with suppressed shrinkage have been desired.

Patent Literature 3 has disclosed that a polysilazane having a ratio of the SiH₂ groups to the SiH₃ groups in one molecule of from 2.5 to 8.4, and an element ratio of Si:N:H=50 to 70% by mass:20 to 34% by mass:5 to 9% by mass is superior in heat resistance, abrasion resistance and chemical resistance and can afford a coating film high in surface hardness and therefore can be suitably used as a binder for a ceramic molded article, especially for a ceramic molded and sintered article. Such a polysilazane, however, has a problem that it undergoes a large shrinkage during a calcination step conducted in water vapor due to its large content of SiH₃ groups and therefore cracking of a silica film readily occurs when calcination is conducted at a temperature of 500° C. or higher.

Patent Literature 4 has disclosed that a composition for forming a protective film for ultra-violet light screening glass, the composition containing as an essential ingredient a polysilazane having a ratio of SiH₃ to the sum total of SiH₁, SiH₂, and SiH₃ in terms of the peak area ratio of a ¹H-NMR spectrum of 0.13 to 0.45 and a number average molecular weight of from 200 to 100,000, is applied to a ultra-violet light screening layer on a glass plane and then heated in dry air to form a protective film superior in dynamic strength and chemical stability.

Patent Literature 5 has disclosed that an interlayer insulating film-forming coating liquid composed of an inactive organic solvent solution of a polysilazane whose ratio of SiH₃ to the sum total of SiH₁ and SiH₂ in terms of the peak area ratio of a ¹H-NMR spectrum has been adjusted to from 0.15 to 0.45 is superior in storage stability and application characteristics and high in insulating properties and can reproducibly form a dense coating film with a good surface profile. It has also been disclosed that the coating liquid can be adjusted by replacing some of active hydrogens of the polysilazane by trimethylsilyl groups and hexylmethyldisilazane is used as an adjusting agent. A polysilazane obtained by reacting hexylmethyldisilazane undergoes a large shrinkage during a calcination step conducted in water vapor and has a problem that cracking in a silica film is prone to occur when calcination is conducted at a temperature of 500° C. or higher.

Patent Literature 6 has disclosed that there is provided an insulating film-forming coating liquid containing an organic solvent and an inorganic polysilazane whose ratio of the peak area at from 4.5 to 5.3 ppm derived from an SiH₁ group and an SiH₂ group to the peak area at from 4.3 to 4.5 ppm derived from an SiH₃ group in a ¹H-NMR spectrum is from 4.2 to 50 can afford a coating liquid for forming an insulating film that undergoes less shrinkage during a calcination step conducted in water vapor and that is less prone to cracking in a silica coating film and exfoliation from a semiconductor substrate, and has also disclosed that there are provided an insulating film using the same and a method for producing a compound to be used for the same. In order to reduce carbon remaining in a silica film, however, calcination at a high temperature may be desired and a further improvement in thermal shrinkage is desired.

### CITATION LIST

### Patent Literature

Patent Literature 1: JP-A-7-223867
Patent Literature 2: U.S. Pat. No. 6,767,641
Patent Literature 3: JP-A-1-138108
Patent Literature 4: JP-A-5-311120
Patent Literature 5: JP-A-10-140087
Patent Literature 6: JP-A-2011-79917

### Non-Patent Literature

Non-Patent Literature 1: Electronic Materials, p. 50, December, 1994

### SUMMARY OF INVENTION

### Technical Problem

Accordingly, an object of the present invention is to provide an inorganic polysilazane that undergoes less shrinkage during a calcination step in an oxidizing agent such as water vapor and is less prone to allow a silica film to suffer from the formation of cracks or peel off from a semiconductor substrate, and a silica film-forming coating liquid containing the inorganic polysilazane.

### Solution to Problem

The present inventor has arrived at the present invention by finding that the molecular weight of an inorganic polysilazane, an SiH₃ group, and a branch extending from a nitrogen atom are related to the shrinkage in the conversion to silica during the calcination step.

The present invention provides an inorganic polysilazane, wherein the value of A/(B+C) is 0.9 to 1.5 and the value of (A+B)/C is 4.2 to 50 where the peak area within the range of from 4.75 ppm to less than 5.4 ppm is represented by A, the peak area within the range of from 4.5 ppm to less than 4.75 ppm is represented by B, and the peak area within the range of from 4.2 ppm to less than 4.5 ppm is represented by C in a ¹H-NMR spectrum; and the polystyrene-equivalent mass average molecular weight is 2000 to 20000.

The present invention also provides a silica film forming coating liquid including the inorganic polysilazane and an organic solvent as essential ingredient.

The present invention also provides a method for forming a silica film, the method including applying the silica film-forming coating liquid onto a substrate, and then reacting the coating liquid with an oxidizer to form a silica film.

### Advantageous Effects of Invention

According to the present invention, it is possible to provide a polysilazane that undergoes less shrinkage during a calcination in the presence of an oxidizing agent.

### BRIEF DESCRIPTION OF DRAWINGS

FIG. 1 is an infrared spectrum chart of an inorganic polysilazane for explaining the method for determining an NH/SiH absorbancy ratio in the present invention.

FIG. 2 is a ¹H-NMR spectrum chart of the silica film-forming coating liquid No. 1 prepared in Example 1.

FIG. 3 is a ¹H-NMR spectrum chart of the silica film-forming coating liquid No. 2 prepared in Example 2.

FIG. 4 is a ¹H-NMR spectrum chart of the silica film-forming coating liquid No. 3 prepared in Example 3.

### DESCRIPTION OF EMBODIMENTS

The present invention will be described in detail below on the basis of preferred embodiments thereof.

The inorganic polysilazane of the present invention is characterized in that the value of A/(B+C) is 0.9 to 1.5 and the value of (A+B)/C is 4.2 to 50 where the peak area within the range of from 4.75 ppm to less than 5.4 ppm is represented by A, the peak area within the range of from 4.5 ppm to less than 4.75 ppm is represented by B, and the peak area within the range of from 4.2 ppm to less than 4.5 ppm is represented by C in a ¹H-NMR spectrum; and the polystyrene-equivalent mass average molecular weight is 2000 to 20000.

The inorganic polysilazane is a polysilazane that contains —SiH₂—NH— as a fundamental unit and has no organic groups in its structure. In general, the inorganic polysilazane is not a linear polymer but a polymer including a branched structure in which a branch extending from a silicon atom or a branch extending from a nitrogen atom, a crosslinked structure, or a cyclic structure is present. It has any of the units of the following S-1 to S-4 as a silicon unit and any of the units of the following N-1 to N-3 as a nitrogen unit.

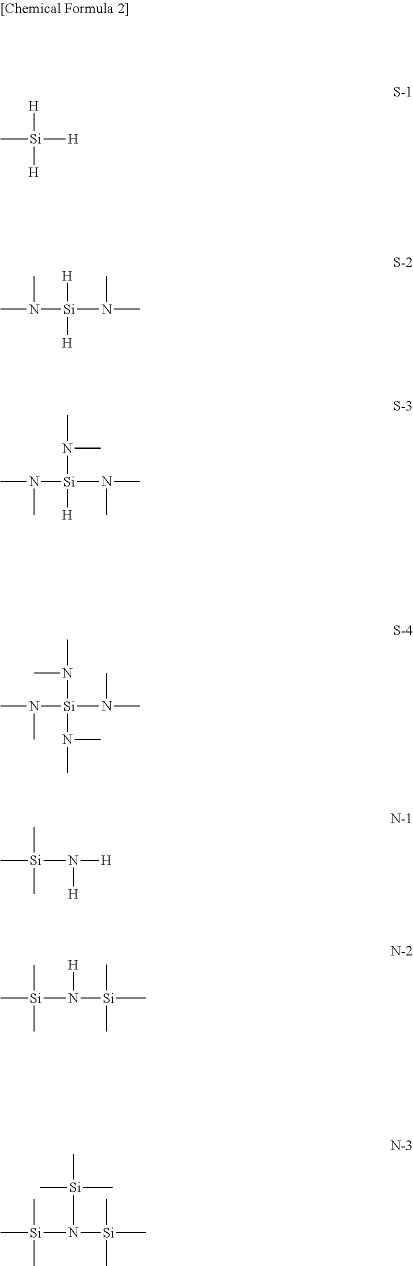

The relative abundance of the above-mentioned units in the inorganic polysilazane can be determined from the absorption spectrum of hydrogen atoms bound to silicon atoms in the ¹H-NMR spectrum of the inorganic polysilazane. The hydrogen atoms of the unit S-1 exhibit absorption in the range of from 4.2 ppm to less than 4.5 ppm. The hydrogen atoms of the unit S-2 and those of the unit S-3 exhibit absorption in the range of from 4.5 ppm to less than 5.4 ppm, and the absorption of the hydrogen atoms of the unit S-3 is present in a lower magnetic field (higher frequency) region than the absorption of the hydrogen atoms of the unit S-2. Moreover, the absorption of the hydrogen atoms bound to the silicon atoms contained in the unit N-3 is present in a lower magnetic field (higher frequency) region than the absorption of the hydrogen atoms bound to the silicon atoms contained in the unit N-2.

The absorption of the hydrogen atoms of the unit S-1 is present in a lower magnetic field region in the case that the unit S-1 is contained in the unit N-3 than the case that the unit S-1 is contained in the unit N-2. These absorptions are broad and are measured to overlap each other. The peak area C in the range of from 4.2 ppm to less than 4.5 ppm in the present invention corresponds to the number of the hydrogen atoms of the —SiH₃ groups in the inorganic polysilazane.

In a ¹H-NMR spectrum, the absorptions in the range of from 4.5 ppm to less than 5.4 ppm are assigned to the absorption of the SiH contained in the unit N-3, the absorption of the SiH₂ contained in the unit N-3, the absorption of the SiH contained in the unit N-2, and the absorption of the SiH₂ contained in the N-2 unit as viewed from the lower magnetic field side.

That is, the lower magnetic field side is assigned to the absorption of the hydrogen atoms bound to the silicon atoms of the unit N-3, and the higher magnetic field side is assigned to the absorption of the hydrogen atoms bound to the silicon atoms of the unit N-2. These peaks are broad and are measured to overlap each other. That the proportion of the absorption area on the lower magnetic field side is larger means that the proportion of the unit N-3 is larger, whereas that the proportion of the absorption area on the higher magnetic field side is larger means that the proportion of the unit N-2 is larger.

When this range is divided at 4.75 ppm, it can be said that the peak area A in the range of from 4.75 ppm to less than 5.4 ppm in the present invention increases as the number of present units N-3 increases and the peak area B in the range of from 4.5 ppm to less than 4.75 ppm increases as the number of present units N-2 increases.

In other words, A/(B+C) in the present invention is a measure of the number of present units N-3 in the inorganic polysilazane and (A+B)/C is a measure of number of the present SiH₃ groups in the inorganic polysilazane.

In the inorganic polysilazane of the present invention, the value of A/(B+C), which is the measure of the number of present units N-3, is from 0.9 to 1.5, preferably from 1.0 to 1.4.

Values of A/(B+C) less than 0.9 are not sufficiently effective for reducing the shrinkage when converted into silica by the calcination step. This is similar if the value is larger than 1.5.

We envisage that the reason why the shrinkage decreases if the value of (A+B)/C is larger than 0.9 is that when unit N-3 is converted into silica, one molecule of nitrogen is replaced by 1.5 molecules of oxygen, increasing the volume occupied by the unit.

In our envisagement, the reason why decrease in shrinkage is not attained if the value of A/(B+C) is larger than 1.5 is that an increase in the number of the unit N-3 leads to decrease in the number of ammonia molecules needed when the inorganic polysilazane is converted into silica and, as a result, the proportion of Si—N bonds converted into Si—O bonds in the inorganic polysilazane decreases and the polysilazane moiety remaining unconverted into silica is lost as outgas, cancelling the effect of the unit N-3 to suppressing shrinkage.

The value of (A+B)/C in the inorganic polysilazane of the present invention is from 4.2 to 50, preferably from 4.5 to 20.

If the value of (A+B)/C is smaller than 4.2, the shrinkage when being converted into silica by the calcination step becomes larger. It is difficult to produce an inorganic polysilazane that value of which is larger than 50. That the value of (A+B)/C is small means that there are many SiH₃ groups, and the SiH₃ groups will be decomposed at the time of conversion into silica, leading to loss as outgas of monosilane. We envisage that the reason why inorganic polysilazanes having a value of (A+B)/C of 50 or more are difficult to produce is that at the time of reaction of ammonia and halosilanes, some of the halosilanes undergo a disproportionation reaction before a polymerization reaction, changing the number of hydrogen atoms adjacent to silicon atoms.

As far as the molecular weight of the inorganic polysilazane of the present invention concerned, the polystyrene-equivalent weight average molecular weight is from 2000 to 20000, preferably from 3000 to 10000.

If the weight average molecular weight is smaller than 2000, the amount of outgassing emitted from a coating film will increase in the drying step or the calcination step during the silica film formation and then decrease in the thickness of the silica film or generation of cracks occurs. If the weight average molecular weight is larger than 20000, the ability to embed a detailed pattern or a pattern large in aspect ratio will deteriorate and it will become difficult to form a good silica film.

The proportions of the components having a mass average molecular weight of 800 or less in the inorganic polysilazane of the present invention is preferably 40% or less, more preferably 30% or less because if low molecular weight components are present in an excessively large amount in the inorganic polysilazane of the present invention, volatiles or sublimates emitted from the coating film during the drying step or the calcination step will increase and decrease in the thickness of a silica film or generation of cracks may occur.

In the present invention, a mass average molecular weight refers to a polystyrene-equivalent mass average molecular weight in the case that GPC analysis is conducted with a differential refractive index detector (RI detector) using tetrahydrofuran (THF) as a solvent. In addition, the proportion of components with mass average molecular weights of 800 or less in the inorganic polysilazane of the present invention refers to the ratio of the amount of polysilazanes with a polystyrene-equivalent mass average molecular weight of 800 or less to the overall amount of all polysilazanes in terms of the peak area ratio of the inorganic polysilazane taken when GPC analysis has been conducted.

In the infrared spectrum of the inorganic polysilazane of the present invention, the absorption derived from an Si—H bond is present at from 2050 to 2400 cm⁻¹ and the absorption derived from an N—H bond is present at from 3300 to 3450 cm⁻¹. Therefore, since the absorbancy at from 2050 to 2400 cm⁻¹ corresponds to the number of hydrogen atoms bound to silicon atoms and the absorbancy at from 3300 to 3450 cm⁻¹ corresponds to the number of hydrogen atoms bound to nitrogen atoms, the ratio of the maximum absorbancy in the range of from 3300 to 3450 cm⁻¹ to the maximum absorbancy in the range of 2050 to 2400 cm⁻¹ in an infrared spectrum serves as an index of (the number of hydrogen atoms bound to nitrogen atoms)/(the number of hydrogen atoms bound to silicon atoms). In the present invention, this ratio is henceforth referred to as an NH/SiH absorbancy ratio.

The NH/SiH absorbancy ratio of the inorganic polysilazane of the present invention is preferably from 0.01 to 0.20, more preferably from 0.10 to 0.20 because if the NH/SiH absorbancy ratio is smaller than 0.01, then the storage stability of the inorganic polysilazane of the present invention may be poor, and if the ratio is greater than 0.20, then higher shrinkage may occur during the conversion to silica by calcination.

The infrared spectrum of the inorganic polysilazane in the present invention may be measured by either transmission or reflection. When measured by transmission, the infrared spectrum can be obtained by applying the inorganic polysilazane to a specimen having substantially no interfering absorption at both from 2050 to 2400 cm⁻¹ and from 3300 to 3450 cm⁻¹, and then measuring an infrared spectrum. When measured by reflection, the measurement can be conducted using a specimen similar to that used for the transmission, but the reflection may be inferior in S/N ratio to the transmission. A method that is simple and good in reproducibility is, for example, a method that involves measuring by transmission an inorganic polysilazane that was applied with a spin coater to a double-sided polished silicon wafer as a substrate and then was dried.

When the thickness of the film of the inorganic polysilazane to be formed on the above-mentioned substrate is within the range of from 300 to 1000 nm, the NH/SiH absorbancy ratio can be determined precisely. For the measurement of an infrared spectrum, it is preferable to use a Fourier Transform infra-red spectrometer (FT-IR) because it allows easy data processing after the measurement.

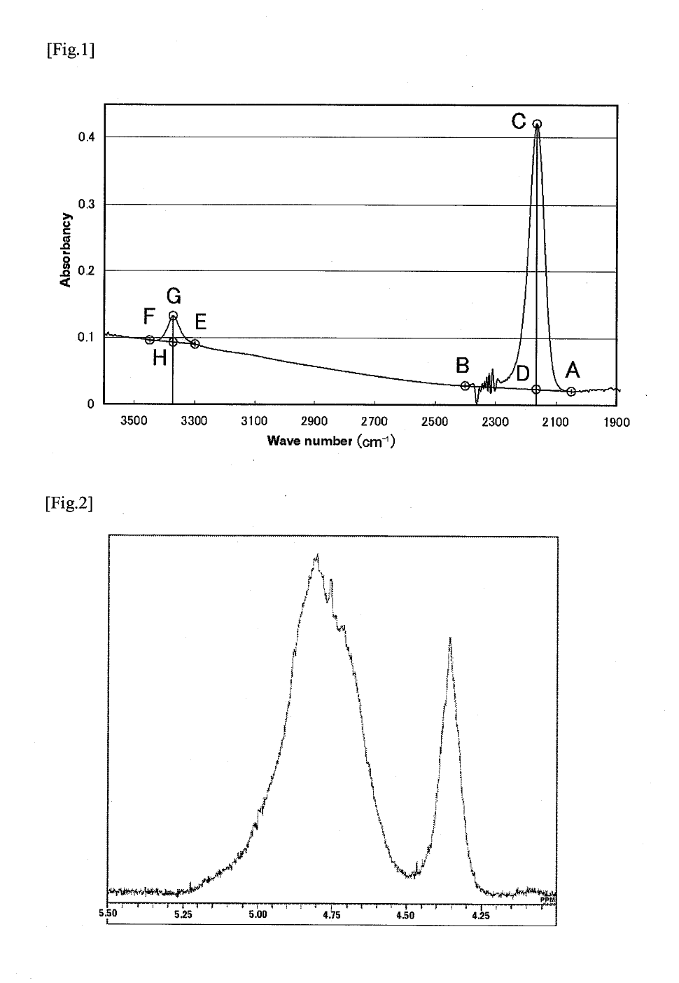

The NH/SiH absorbancy ratio used in the present invention is a value obtained by a peak intensity method from a spectrum chart of the infrared spectrum of the inorganic polysilazane. For example, in FIG. 1, when the points on the absorbance curve at 2050 cm⁻¹, 2400 cm⁻¹, 3300 cm⁻¹, and 3450 cm⁻¹ are denoted by point A, point B, point E, and point F, respectively, the points on the absorbance curve at the frequencies where the absorbency is maximum within the range of from 2050 to 2400 cm⁻¹ and the range of from 3300 to 3450 cm⁻¹ are denoted by point C and point G, respectively, the intersection of the perpendicular from the point C to the reference line (the line on which the absorbancy is zero; blank) and the line AB is denoted by point D, and the intersection of the perpendicular from the point G to the reference line and the line EF is denoted by point H, the NH/SiH absorbancy ratio corresponds to the length ratio of the line segment GH to the line segment CD. That is, the NH/SiH absorbancy ratio of the present invention is the ratio of the maximum absorbancy at from 3300 to 3450 cm⁻¹ with respect to a baseline that is a line connecting the point of the absorbancy at 3300 cm⁻¹ and the point of the absorbancy at 3450 cm⁻¹ in the spectrum chart of the infrared spectrum of the inorganic polysilazane to the maximum absorbancy at from 2050 to 2400 cm⁻¹ with respect to a baseline that is a line connecting the point of the absorbancy at 2050 cm⁻¹ and the point of the absorbancy at 2400 cm⁻¹ in that chart.

It is usual for inorganic polysilazanes that the absorbancy becomes maximum within the range of from 2050 to 2400 cm⁻¹ at about 2166 cm⁻¹ and the absorbancy becomes maximum within the range of from 3300 to 3450 cm⁻¹ at about 3377 cm⁻¹.

The inorganic polysilazane of the present invention preferably has an index of refraction at a wavelength of 633 nm of from 1.550 to 1.650, more preferably from 1.560 to 1.640, and even more preferably from 1.570 to 1.630 because if the index of refraction at a wavelength of 633 nm is smaller than 1.550, then higher shrinkage may occur during the conversion to silica by calcination, whereas if the index of refraction is larger than 1.650, then the storage stability of the silica film-forming coating liquid of the present invention may be poor.

As to the method for measuring the above-mentioned index of refraction, it may be measured after applying an inorganic polysilazane or a composition in which an inorganic polysilazane has been dissolved or dispersed to a substrate by such a method as spin coating, dip coating, knife coating, or roll coating, and then drying it to form an inorganic polysilazane film. Although varying depending upon the thickness of the film of the inorganic polysilazane, the drying is conducted by heating at 150° C. for one minute or more, preferably at 150° C. for about three minutes when the thickness is from 500 to 1000 nm. Of inorganic polysilazanes having the same ratio of the nitrogen content to the silicon content, a polysilazane higher in index of refraction is lower in hydrogen content and has a larger number of cyclic structures in the molecule; this is speculated to influence the storage stability of the silica film-forming coating liquid and the shrinkage during the calcination step in water vapor.

The method for producing the inorganic polysilazane of the present invention is not particularly restricted, and the production may be conducted by applying or using a well-known method for producing an inorganic polysilazane. For example, a halosilane compound is reacted with ammonia directly or alternatively an adduct in which an additive such as a base has been added to a halosilane compound is formed and then the adduct is reacted with ammonia. The method for producing an inorganic polysilazane via such an adduct has been disclosed in, for example, JP-A-60-145903 and JP-A-61-174108.

As the method for producing the inorganic polysilazane of the present invention, a method in which a halosilane compound is reacted with a base to form an adduct and then the adduct is reacted with ammonia is preferable in that the reaction can be controlled.

In the method for producing an inorganic polysilazane in which an adduct is formed by reacting a halosilane compound with a base and then the adduct is reacted with ammonia, the reaction of the adduct with ammonia is usually conducted at a temperature of from −50 to 20° C., preferably from −10 to 15° C.

Examples of the halosilane compound to be used as a raw material for the inorganic polysilazane of the present invention include dihalosilane compounds, such as dichlorosilane, dibromosilane, and chlorobromosilane; trihalosilane compounds, such as trichlorosilane, tribromosilane, dichlorobromosilane, and chlorodibromosilane, tetrachlorosilicane, and tetrabromosilane, and chlorosilanes are preferable as the halosilane because of their inexpensiveness. Halosilane compounds may be used singly and they may be used in combination of two or more thereof. Inorganic polysilazanes prepared using dihalosilane compounds are advantageously superior in film forming property and inorganic polysilazanes prepared using trihalosilane compounds advantageously undergo less shrinkage at the time of calcination. Therefore, in producing the inorganic polysilazane of the present invention, it is preferred to use a dihalosilane compound, or a trihalosilane compound, or a dihalosilane compound and a trihalosilane compound in admixture.

When a dihalosilane compound and a trihalosilane compound are used in admixture, as far as their proportions concerned, the amount of the trihalosilane compound per mol of the dihalosilane compound is preferably from 0.01 to 2 mol, more preferably from 0.03 to 1 mol, even more preferably from 0.05 to 0.5 mol in terms of controlling the number of the unit S-2.

The base, which is the additive for forming the adduct, is preferably a base that is inert to reactions other than the reaction for forming the adduct with the halosilane compound. Examples of such a base include tertiary amines such as trimethylamine, triethylamine, tributylamine, and dimethylaniline; and pyridines such as pyridine and picoline; pyridine and picoline are preferable in terms of industrial availability and handling ease, and pyridine is more preferable. The amount of the base used should just be one-fold molar excess relative to the halogen atoms of the halosilane compound and is preferably equal to or more than 1.1-fold molar excess so as to ensure that the formation of the adduct is not insufficient.

In the method for producing the inorganic polysilazane of the present invention, because the formation of the above-mentioned adduct reduces the flowability of the reaction system, it is preferable to perform the reaction to form the adduct in an organic solvent. As the solvent, an organic solvent non-reactive with inorganic polysilazanes can be used. Examples thereof include saturated chain hydrocarbon compounds, such as pentane, hexane, heptane, octane, 2,2,4-trimethylpentane (also called isooctane), isononane, and 2,2,4,6,6-pentamethylheptane (also called isododecane); saturated cyclic hydrocarbon compounds, such as cyclopentane, cyclohexane, methylcyclohexane, ethylcyclohexane, and decalin; aromatic hydrocarbon compounds, such as benzene, toluene, xylene, ethylbenzene, cumene, pseudocumene, and tetralin; and ether compounds, such as diethyl ether, dipropyl ether, diisopropyl ether, dibutyl ether, diisobutyl ether, tert-butyl methyl ether, tetrahydrofuran, dioxane, and 1,2-dimethoxyethane.

As a reaction solvent instead of the organic solvent, the base that is an additive is used in an excessive amount and the excessive amount of the base may be used as such a solvent. Particularly preferable is to use pyridine as an additive in an excessive amount enough for maintaining flowability even after the completion of the formation reaction and use no other organic solvents. In this case, the amount of pyridine used is preferably from 3 to 30-fold molar excess, more preferably from 4 to 25-fold molar excess, even more preferably from 5 to 20-fold molar excess relative to the halosilane compound. In order to prevent the flowability from decreasing due to the adduct formation, a halosilane compound and ammonia may be charged separately into an organic solvent, an additive, and a mixed solvent containing an organic solvent and an additive or alternatively they may be charged continuously at the same time.

In the production method via an adduct, the amount of ammonia used should just be equimolar or more (i.e., 1-fold molar excess or more) relative to the halogen atom of the halosilane compound to be used for the reaction from a stoichiometric standpoint. Taking into consideration sufficiency for completing the reaction and economic efficiency, however, the amount of ammonia used is preferably from 1.0 to 3.0-fold molar excess, more preferably from 1.1 to 2.5-fold molar excess, even more preferably from 1.2 to 2.0-fold molar excess relative to the halogen atom of the halosilane compound to be used for the reaction.

After the reaction with ammonia, an excess of ammonia is removed as required, and an ammonium halide formed is removed by filtration or the like. This may, as required, be followed by, for example, solvent replacement by a desired organic solvent by a conventional method.

The inorganic polysilazane of the present invention may be made to undergo cyclization by an intramolecular reaction, increase in molecular weight by an intermolecular reaction, etc. by forming Si—N bonds by reacting SiH groups and NH groups in the inorganic polysilazane molecule before or after the removal of a salt formed, and it is allowed to thereby conduct control, such as reduction in the number of SiH₃ groups, increase in mass average molecular weight, reduction in the amount of components having a mass average molecular weight of 800 or less, increase in the NH/SiH absorbancy ratio, and increase in index of refraction. Examples of the method for forming an Si—N bond by reacting an Si—H group with an NH group of the inorganic polysilazane include a method that involves heating in an basic solvent such as pyridine and picoline (see, for example, JP-A-1-138108), a method using an alkali metal-containing basic catalyst, such alkali metal hydrides, alkali metal alkoxides, and anhydrous alkali metal hydroxides (see, for example, JP-A-60-226890), a method using a quaternary ammonium compounds such as tetramethylammonium hydroxide as a catalyst (see, for example, JP-T-5-170914), and a method using an acid catalyst such as ammonium nitrate and ammonium acetate (see, for example, JP-T-2003-514822), and preferable is a method that involves heating in an additive used for the reaction or a solvent containing the additive.

In the case of producing an inorganic polysilazane by a method via an adduct, since an adduct (e.g., dichlorosilane and pyridine) reacts with ammonia to release an additive (e.g., pyridine), the additive released may be used as a basic solvent. Therefore, it is preferable, in terms of effective use of raw materials and simplification of the production process, to produce an inorganic polysilazane via an adduct, then heat the released additive as a solvent to react SiH groups and NH groups of the inorganic polysilazane, thereby forming Si—N bonds.

The silica film-forming coating liquid of the present invention is a composition containing the above-described inorganic polysilazane of the present invention and an organic solvent as essential ingredient and it is adjusted to have a concentration convenient for easy application to a substrate.

The organic solvent to be used for the silica film-forming coating liquid of the present invention is not be particularly restricted if it is not a substance that reacts with an inorganic polysilazane to cause deterioration or reaction to an extent high enough to impair the spreadability. Since a hydroxy group, an aldehyde group, a ketone group, a carboxyl group, an ester group, etc. highly reactive with inorganic polysilazanes, solvents failing to have such groups are preferred. Examples of preferable organic solvents for the silica film-forming coating liquid of the present invention include saturated chain hydrocarbon compounds, such as pentane, hexane, heptane, octane, 2,2,4-trimethylpentane (also called isooctane), isononane, and 2,2,4,6,6-pentamethylheptane (also called isododecane); saturated cyclic hydrocarbon compounds, such as cyclopentane, cyclohexane, methylcyclohexane, and decalin; aromatic hydrocarbon compounds, such as benzene, toluene, xylene, ethylbenzene, cumene, pseudocumene, and tetralin; and ether compounds, such as diethyl ether, dipropyl ether, diisopropyl ether, dibutyl ether, diisobutyl ether, tert-butyl methyl ether, tetrahydrofuran, dioxane, and 1,2-dimethoxyethane; xylene and dibutyl ether are preferable because of good spreadability, and dibutyl ether is more preferable because of good storage stability. Although organic solvents may be used singly, they may be used in combination of two or more thereof for the purpose of evaporation rate adjustment, etc.

Ether compounds may contain alcohol compounds, aldehyde compounds, ketone compounds, carboxylic acid compounds, ester compounds, etc. as their raw materials, by-products formed during their production processes, and degradation products formed during storage. Because a larger shrinkage may occur in a calcination step if these compounds are contained in the organic solvent for the silica film-forming coating liquid of the present invention, it is preferable to adjust the sum total of the contents of such alcohol compounds, aldehyde compounds, ketone compounds, carboxylic acid compounds, and ester compounds to 0.1% by mass or less, more preferably 0.05% by mass or less, even more preferably 0.01% by mass or less to dibutyl ether before mixing the solvent with an inorganic polysilazane.

Because if the content of the inorganic polysilazane in the silica film-forming coating liquid of the present invention is excessively low, then a property to form a silica film becomes insufficient, whereas if the content is excessively high, the storage stability of the silica film-forming coating liquid of the present invention may become insufficient, resulting in the formation of a gel matter, the content of the inorganic polysilazane is preferably from 1 to 40% by mass, more preferably from 3 to 35% by mass, even more preferably from 5 to 30% by mass.

The silica film-forming coating liquid of the present invention can be used mainly in the form of a silica film formed for by applying the coating liquid to a substrate (a target material) and reacting the coating liquid with an oxidizing agent, for applications for which inorganic polysilazanes have heretofore been used, such as insulating films for semiconductor devices, protective films for flat panel displays, and antireflection films for optical-related products, and especially it can be used suitably for insulating films for semiconductor devices.

For example, when forming an insulating film for a semiconductor device, preferred is a production method including an application step of applying the silica film-forming coating liquid of the present invention to a target material (a substrate) to form a coating film, a drying step of removing an organic solvent from the coating film, and a calcination step of conducting calcination in a water vapor to form a silica film.

In the case of applying the silica film-forming coating liquid of the present invention to the target material, any application method may be used with no particular limitations, such as a spraying method, a spin coating method, a dip coating method, a roll coating method, a flow coating method, a screen printing method, and a transfer printing method, and the spin coating method is preferable because a coating film that is small and uniform in thickness can thereby be formed.

Although the drying temperature and time of the drying step may vary depending upon the organic solvent to be used and the thickness of the coating, it is preferable to heat at from 80 to 200° C., preferably from 120 to 170° C. for from 1 to 30 minutes, more preferably from 2 to 10 minutes. The drying atmosphere may be any of in oxygen, in air, and in an inert gas. Suitable ranges for the calcination step include a water vapor atmosphere having a relative humidity of from 20 to 100% and a temperature of from 200 to 1200° C. The temperature for the calcination conducted under a water vapor atmosphere is preferably from 300 to 1000° C., more preferably from 700 to 900° C. because if the calcination temperature is lower, the reaction may fail to sufficiently proceed and deterioration in insulating properties may be caused by the persistence of silanol groups, whereas higher calcination temperatures will cause problems with production cost. In conducting calcination, the calcination may be conducted in one stage at a temperature of 700° C. or higher or alternatively may be conducted in a two-stage process in which calcination is conducted at from 200 to 500° C., preferably at from 300 to 450° C., for from 30 to 60 minutes and then calcination is further conducted at from 450 to 1200° C., preferably at from 600 to 100° C., more preferably at from 700 to 900° C. The two-stage calcination is preferred because the silica film undergoes less shrinkage and hardly suffers from cracks. Besides, a low temperature calcination process in which calcination is conducted at from 200 to 500° C., preferably at from 350 to 450° C., for from 30 to 60 minutes, followed by immersion into distilled water of from 20 to 80° C. (see, for example, JP-A-7-223867) is available. It, however, is preferable to heat at from 700 to 900° C. for from about 5 to about 60 minutes in the air after low temperature calcination because deterioration in insulating properties may be caused by the persistence of silanol groups in the low temperature calcination process.

### EXAMPLES

The present invention will be described concretely below with reference to Examples, but they do not limit the scope of the present invention. The “part(s)” and “%” in Examples are on the mass basis. The dibutyl ether used as a solvent had a purity of 99.99% and a total content of alcohol compounds, aldehyde compounds, ketone compounds, carboxylic acid compounds, and ester compounds of 0.01% or less.

### Example 1

A 3000-ml glass reaction vessel equipped with a stirrer, a thermometer, and an inlet tube was charged with 2310 g (29.2 mol) of dry pyridine, and then 48.6 g (0.36 mol) of trichlorosilane and 82.6 g (0.82 mol) of dichlorosilane were each dropped over one hour under stiffing and cooling so that the reaction temperature might be 0 to 5° C., forming a pyridine adduct. Ammonia in an amount of 78.9 g (4.64 mol) was fed through the inlet tube over three hours under cooling so that the reaction temperature might not exceed 10° C., and stirring was further conducted at 10° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a silica film-forming coating liquid No. 1 having an inorganic polysilazane content of 11.3%.

### Example 2

A 3000-ml glass reaction vessel equipped with a stirrer, a thermometer, and an inlet tube was charged with 2310 g (29.2 mol) of dry pyridine, and then 50.4 g (0.37 mol) of trichlorosilane and 82.9 g (0.82 mol) of dichlorosilane were each dropped over one hour under stiffing and cooling so that the reaction temperature might be −10 to 0° C., forming a pyridine adduct. Ammonia in an amount of 78.9 g (4.61 mol) was fed through the inlet tube over three hours under cooling so that the reaction temperature might not exceed 5° C., and stirring was further conducted at 10° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a silica film-forming coating liquid No. 2 having an inorganic polysilazane content of 18.7%.

### Example 3

A 3000-ml glass reaction vessel equipped with a stirrer, a thermometer, and an inlet tube was charged with 2411 g (30.5 mol) of dry pyridine, and then 69.8 g (0.52 mol) of trichlorosilane and 51.3 g (0.51 mol) of dichlorosilane were each dropped over one hour under stiffing and cooling so that the reaction temperature might be −10 to 0° C., forming a pyridine adduct. Ammonia in an amount of 74.4 g (4.35 mol) was fed through the inlet tube over three hours at a reaction temperature of from −10 to 0° C., and stirring was further conducted at 10° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a silica film-forming coating liquid No. 3 having an inorganic polysilazane content of 9.64%.

### Comparative Example 1

A 3000-ml glass reaction vessel equipped with a stirrer, a thermometer, and an inlet tube was charged with 1646 g (20.8 mol) of dry pyridine, and then 310 g (3.1 mol) of dichlorosilane was fed through the inlet tube over one hour at a reaction temperature of from 0 to 5° C., forming a pyridine adduct of dichlorosilane. Ammonia in an amount of 180 g (10.6 mol) was fed through the inlet tube over one hour at a reaction temperature of from 0 to 5° C., and stiffing was further conducted at 10° C. for 1.5 hours, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was filtered through a cartridge filter made of PTFE with a filtration diameter of 0.1 μm under a nitrogen atmosphere, resulting in a comparative coating liquid 1 having an inorganic polysilazane content of 19.0%.

### Comparative Example 2

A 3000-ml glass reaction vessel equipped with a stirrer, a thermometer, and an inlet tube was charged with 2248 g (28.4 mol) of dry pyridine, and then 191.0 g (1.89 mol) of dichlorosilane and 113.0 g (6.65 mol) of ammonia were each fed over three hours under stiffing and cooling so that the reaction temperature might be 0 to 5° C., and stirring was further conducted at 10° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a comparative coating liquid 2 having an inorganic polysilazane content of 19.2%.

### Comparative Example 3

A 3000-ml glass reaction vessel equipped with a stirrer, a thermometer, and an inlet tube was charged with 2044 g (25.8 mol) of dry pyridine, and then 174.0 g (1.72 mol) of dichlorosilane and 103.0 g (6.06 mol) of ammonia were each fed over three hours under stirring and cooling so that the reaction temperature might be 0 to 5° C., and stirring was further conducted at 10° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a comparative coating liquid 3 having an inorganic polysilazane content of 19.3%.

### Comparative Example 4

A 3000-ml glass reaction vessel equipped with a stirrer, a thermometer, and an inlet tube was charged with 2303 g (29.1 mol) of dry pyridine, and then 280.0 g (2.77 mol) of dichlorosilane and 165.0 g (9.71 mol) of ammonia were each fed over four hours under stirring and cooling so that the reaction temperature might be −10 to 0° C., and stirring was further conducted at 0° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a comparative coating liquid 4 having an inorganic polysilazane content of 19.0%.

### Comparative Example 5

A 3000-ml glass reaction vessel equipped with a stirrer, a thermometer, and an inlet tube was charged with 2044 g (25.8 mol) of dry pyridine, and then 325.7 g (3.22 mol) of dichlorosilane and 192.1 g (11.3 mol) of ammonia were each fed over two hours under stirring and cooling so that the reaction temperature might be −10 to 0° C., and stirring was further conducted at 0° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a comparative coating liquid 5 having an inorganic polysilazane content of 19.2%.

### Comparative Example 6

A 3000-ml glass reaction vessel equipped with a stirrer, a thermometer, and an inlet tube was charged with 2044 g (25.8 mol) of dry pyridine, and then 260.6 g (2.58 mol) of dichlorosilane and 131.6 g (7.74 mol) of ammonia were each fed over 1.5 hours under stirring and cooling so that the reaction temperature might be −10 to 0° C., and stirring was further conducted at 0° C. for 1.5 hours under blowing nitrogen gas, so that the reaction was completed. The resulting reaction liquid was heated to 10° C. and ammonium chloride formed was separated by filtration under a nitrogen atmosphere and then an excess of ammonia was removed under reduced pressure, followed by solvent exchange from pyridine to dibutyl ether. The resulting solution was heated at 120° C. for six hours and then filtered through a cartridge filter made of PTFE with a filtration diameter of 0.1 μm, resulting in a comparative coating liquid 6 having an inorganic polysilazane content of 20.3%.

### Comparative Example 7

A 5000-ml glass reaction vessel equipped with a stirrer, a thermometer, and an inlet tube was charged with 4300 g (54.4 mol) of dry pyridine, and then 545 g (5.4 mol) of dichlorosilane was fed through the inlet tube over one hour at a reaction temperature of from −40 to −30° C., forming a pyridine adduct of dichlorosilane. Ammonia in an amount of 325 g (19.1 mol) was fed through the inlet tube over one hour at a reaction temperature of from −40 to −30° C., and stirring was further conducted at from −20 to −15° C. for 1.5 hours, so that the reaction was completed. The resulting reaction liquid was heated to 25° C. and ammonium chloride formed was separated by filtration under a nitrogen atmosphere and then an excess of ammonia was removed under reduced pressure, followed by exchanging the solvent from pyridine to dibutyl ether by a conventional method. Moreover, filtration was conducted using a cartridge filter made of PTFE with a filtration diameter of 0.1 μm, resulting in a comparative coating liquid 7 having an inorganic polysilazane content of 19.0%.

### Comparative Example 8

A comparative coating liquid 8 having an inorganic polysilazane content of 19.1% was obtained by conducting the same operations as those of Comparative Example 7 except for changing the reaction temperature of ammonia from “from −40 to −30° C.” to “from −15 to −12° C.” in Comparative Example 7 and then stirring at from −15 to −12° C. for two hours.

### Comparative Example 9

A comparative coating liquid 9 having an inorganic polysilazane content of 19.2% was obtained by conducting the same operations as those of Comparative Example 7 except for using a mixture of 444 g (4.4 mol) of dichlorosilane and 13.6 g (1.0 mol) of trichlorosilane instead of 545 g (5.4 mol) of dichlorosilane in Comparative Example 7 and increasing the amount of ammonia from 325 g (19.1 mol) to 340 g (20.0 mol).

### <Analysis: ¹H-NMR Analysis>

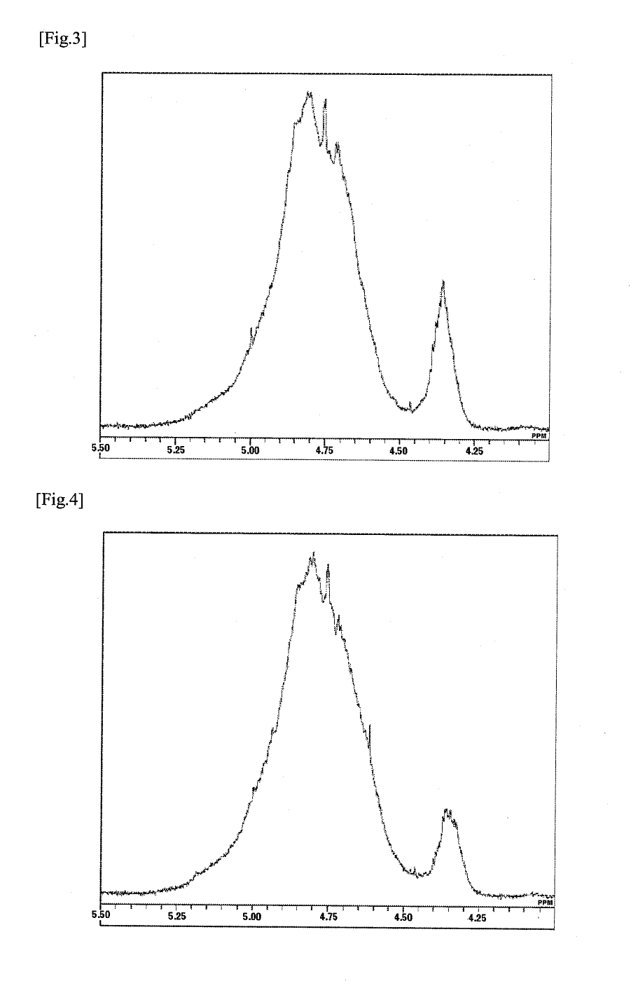

1H-NMR was measured for the silica film-forming coating liquid Nos. 1 to 3 obtained in Examples 1 to 3 and the comparative coating liquids 1 to 9 obtained in Comparative Examples 1 to 9. The charts of the silica film-forming coating liquids No. 1 to 3 are shown in FIG. 2 to FIG. 4. In a ¹H-NMR spectrum, a value of A/(B+C) and a value of (A+B)/C were calculated where the peak area within the range of from 4.75 ppm to less than 5.4 ppm was represented by A, the peak area within the range of from 4.5 ppm to less than 4.75 ppm was represented by B, and the peak area within the range of from 4.2 ppm to less than 4.5 ppm was represented by C. The results are shown in [Table 1].

### <Analysis: GPC>

For the silica film-forming coating liquid Nos. 1 to 3 obtained in Examples 1 to 3 and the comparative coating liquids 1 to 9 obtained in Comparative Examples 1 to 9, the mass average molecular weight of an inorganic polysilazane and the contents of components having a mass average molecular weight of 800 or less were calculated from the result of GPC. The results are shown in [Table 1]. The column used was SuperMultiporeHZ-M manufactured by TOSOH Corporation.

### <Analysis of Inorganic Polysilazane Coating Film: Thickness, IR Analysis>

Each of the silica film-forming coating liquid Nos. 1 to 3 obtained in Examples 1 to 3 and the comparative coating liquids 1 to 9 obtained in Comparative Examples 1 to 9 was applied to a 4-inch thick, double-sided polished silicon wafer by a spin coating method so that the film thickness of the inorganic polysilazane after drying would become from 580 to 620 nm, followed by drying at 150° C. for 3 minutes. Thus a silicon wafer having thereon a coating film of an inorganic polysilazane was prepared, and then the thickness and the FT-IR of the coating film were measured. In the FT-IR measurement was used as a reference a double-sided polished silicon wafer. The film thickness was measured using an F-20 manufactured by Filmetrics. The NH/SiH absorbancy ratio calculated from the film thickness and the result of FT-IR is shown in Table 1.

TABLE 1

| | | | | | |
|---|---|---|---|---|---|
| | | | contents of | | |
| | | | components | | |
| | | mass | having a mass | film | NH/SiH |
| | | average | average molecular | thick- | absor- |
| A/(B + | (A + | molecular | weight of 800 or | ness | bancy |
| C) | B)/C | weight | less (%) | (nm) | ratio |

silica film-forming coating liquid

| | | | | | | |
|---|---|---|---|---|---|---|
| No. 1 | 1.04 | 4.6 | 7000 | 15.9 | 595 | 0.14 |
| No. 2 | 1.19 | 8.8 | 8500 | 13.3 | 601 | 0.15 |
| No. 3 | 1.31 | 13.3 | 4200 | 20.2 | 600 | 0.17 |

comparative coating liquid

| | | | | | | |
|---|---|---|---|---|---|---|
| 1 | 0.85 | 4.1 | 4000 | 11.2 | 600 | 0.13 |
| 2 | 0.97 | 4.0 | 4900 | 13.6 | 598 | 0.092 |
| 3 | 0.91 | 3.6 | 4100 | 11.4 | 602 | 0.10 |
| 4 | 0.86 | 4.3 | 7200 | 8.9 | 600 | 0.11 |
| 5 | 0.65 | 5.3 | 3600 | 11.8 | 597 | 0.14 |
| 6 | 0.84 | 4.8 | 2400 | 12.4 | 596 | 0.10 |
| 7 | 0.87 | 9.4 | 3200 | 11.6 | 601 | 0.099 |
| 8 | 0.86 | 6.2 | 3600 | 10.5 | 600 | 0.13 |
| 9 | 0.88 | 27.4 | 4400 | 9.2 | 598 | 0.11 |

### Example 4 and Comparative Example 10

Using a silicon wafer the same as that used for the above-described analysis of the coating film of an inorganic polysilazane, a silica insulating film was formed by conducting calcination for 30 minutes as a first calcination in an oven conditioned at a relative humidity of 90% and a temperature of 300° C. and for 30 minutes as a second calcination in an oven conditioned at a relative humidity of 10% and a temperature of 900° C. The thickness of the silica film was then measured. The ratio of the thickness of the silica insulating film to the thickness of the inorganic polysilazane after drying was used as a cure shrinkage ratio (%). The results are shown in [Table 2].

TABLE 2

| | cure shrinkage |
|---|---|
| | ratio (%) |
| silica film-forming | |
| coating liquid | |
| No. 1 | 16.5 |
| No. 2 | 15.3 |
| No. 3 | 15.1 |
| comparative coating | |
| liquid | |
| 1 | 18.0 |
| 2 | 17.9 |
| 3 | 18.2 |
| 4 | 19.7 |
| 5 | 20.8 |
| 6 | 18.4 |
| 7 | 17.3 |
| 8 | 17.8 |
| 9 | 16.8 |

The results given in the above-mentioned [Table 1] and [Table 2] clearly show that the silica film-forming coating liquid containing the inorganic polysilazane of the present invention wherein the value of A/(B+C), the value of (A+B)/C, and the mass average molecular weight are within the prescribed ranges are smaller in cure shrinkage ratio and less prone to allow a silica film to crack or peel off from a semiconductor substrate as compared with the comparative coating liquids each containing an inorganic polysilazane whose value of A/(B+C), value of (A+B)/C, and mass average molecular weight are out of the prescribed ranges.

1. An inorganic polysilazane, wherein the value of A/(B+C) is 0.9 to 1.5 and the value of (A+B)/C is 4.2 to 50 where the peak area within the range of from 4.75 ppm to less than 5.4 ppm is represented by A, the peak area within the range of from 4.5 ppm to less than 4.75 ppm is represented by B, and the peak area within the range of from 4.2 ppm to less than 4.5 ppm is represented by C in a ¹H-NMR spectrum; and the polystyrene-equivalent mass average molecular weight is 2000 to 20000.

2. The inorganic polysilazane according to claim 1, wherein the ratio of the maximum absorbancy within the range of 3300 to 3450 cm⁻¹ to the maximum absorbancy within the range of from 2050 to 2400 cm⁻¹ is 0.01 to 0.20.

3. The inorganic polysilazane according to claim 1, wherein the inorganic polysilazane is obtained by reacting a dihalosilane compound, a trihalosilane compound, or a mixture thereof with a base to form an adduct, and then reacting the adduct with ammonia.

4. A silica film forming coating liquid comprising the inorganic polysilazane according to claim 1 and an organic solvent as essential ingredient.

5. A method for forming a silica film, the method comprising applying the silica film-forming coating liquid according to claim 4 onto a substrate, and then reacting the coating liquid with an oxidizer to form a silica film.

6. The inorganic polysilazane according to claim 2, wherein the inorganic polysilazane is obtained by reacting a dihalosilane compound, a trihalosilane compound, or a mixture thereof with a base to form an adduct, and then reacting the adduct with ammonia.

7. A silica film forming coating liquid comprising the inorganic polysilazane according to claim 2 and an organic solvent as essential ingredient.

8. A silica film forming coating liquid comprising the inorganic polysilazane according to claim 3 and an organic solvent as essential ingredient.
